(19) United States
(12) Patent Application Publication
(10) Pub. No.: US 2007/0181421 A1
(43) Pub. Date: Aug. 9, 2007

(54) Sputtering system providing large area sputtering and plasma-assisted reactive gas dissociation

(75) Inventors: Hung-Wen Wei, Hsinchu (TW); Hung-Che Ting, Hsinchu (TW); Hsueh-Ying Chen, Hsinchu (TW)

Correspondence Address: BACON & THOMAS, PLLC, 625 SLATERS LANE, FOURTH FLOOR, ALEXANDRIA, VA, 22314, US

(73) Assignee: Industrial Technology Research Institute, Hsinchu (TW)

(21) Appl. No.: 11/398,684

(22) Filed: Apr. 6, 2006

(30) Foreign Application Priority Data
Feb. 9, 2006 (TW) 95104326

(51) Int. Cl. C23C 14/00

(52) U.S. Cl. 204/298.02

(57) ABSTRACT

This invention provides a sputtering system providing large area sputtering and plasma-assisted reactive gas dissociation. A plurality of plasma sources is provided in a reaction chamber to dissociate at least one reactive gas. The dissociated reactive gas is doped in a film during the deposition of the film so as to control the composition of the film. The property of the film is thus improved. A composite film can be formed on the substrate by the present sputtering system. The present sputtering system is suitable for film deposition on a large-area hard substrate and flexible substrate.

### BACKGROUND OF THE INVENTION

1. Field of the invention

The present invention relates to a sputtering system provided with a plurality of reactive gas plasma sources; more particularly to a sputtering system providing large area sputtering and plasma-assisted reactive gas dissociation.

2. Description of the Related Art

The silicon-based electronic devices need to take a trade-off between manufacturing temperatures and characteristics of the devices. It is a challenge to produce high-performance devices with silicon-based materials by low-temperature manufacturing processes. The low-temperature manufacturing process of thin film transistors can improve the development of the flexible electronic devices. These devices, such as large size high resolution display, wearable calculator and film-like display etc, have characteristics of flexible, light-weight, impact-resistant and low cost. As so far, the flexible electronic devices mainly adopt hydrogenated amorphous silicon (α-Si:H) and organic semiconductor as base materials. However, the performance of the devices is constricted due to low electrons mobility of the channel material. In practice, the performances of these silicon-based electronic devices haven't been sufficient to be as the transistors applicable in the calculators and current-driven organic light-emitting diode display (OLED). The silicon-based material has a small energy band-gap and is opaque. It is not easy to produce transparent electronic circuit with the silicon-based material. New semiconductor material named as “transparent amorphous oxide semiconductor”, such as In—Ga—Zn—O-systems (α-IGZO), Zn—Sn—O-systems (ZTO) and In—Sn—O-systems (α-ITO) etc., is used as the channel material of the active transparent thin film transistor to produce flexible transparent displays.

The methods for depositing amorphous oxide semiconductor material on the substrates include pulse laser deposition (PLD) and physical vapor deposition (PVD). The pulse laser deposition uses high power laser pulses to impact the target to be sputtered. When atoms or atom clusters on the surface of the target obtain sufficient energy to vaporize and then escape from the surface of the target. The vaporized atoms or atom clusters completely fill the chamber, and a portion of the atoms or atom clusters is deposited on the substrate to form the thin film. The PVD is so-called sputtering in generally, by which a target is placed on a electrode applied with high negative bias voltage, and inert gas with larger atomic weight, such as argon gas (Ar), is introduced into the chamber. Argon atoms are ionized by the energetic electron impact to form argon ions, and the argon ions are accelerated by direct current plasma sheath to bombard the target. Then, the atoms and atom clusters on the target are bombarded out. A magnet is positioned on the negative electrode to form a magnetic field on the surface of the target. The electrons are then bound on the surface of the target by the magnetic field so as to increase the density of the argon ions. The sputtering efficiency is thus improved. A portion of atoms of the target is bombarded out by argon ions, diffusing and depositing on the substrate to form the thin film.

U.S. Pat. No. 5,423,970 provides a sputtering system as shown in FIG. 1, in which a conductive target 10 is placed on a negative electrode 12 coupled to a direct current power supply 11. If the target is an insulator, the direct current power supply is replaced by a radio frequency alternating current power supply. Inert gas 13 is introduced into the chamber to be used as sputtering gas. Argon gas with larger atomic weight is used as the sputtering gas. For increasing electrical ionization rate on the surface of the target 10, a magnet is positioned on the negative electrode 12 to form a magnetic field so as to bound electrons on the surface of the target 10. During the thin film deposition process, a substrate 14 is slowly rotated such that the thin film can be evenly deposited on the substrate. Some elements of the components sputtered out from the target are dispersed into vacuum during the thin film deposition process. The resultant composition of the thin film is not as expected. Hence, it is necessary to add reactive gas 15 in the process gas except for argon gas. For example, when depositing an Indium-Tin Oxide film, oxygen gas is mixed in the process gas so as to control the proportion of oxygen atoms in the thin film. Because some targets are expensive, when adopting magnetic field to bound electrons on the surface of the target, it will cause un-evenly sputtering on the target. In order to efficiently utilize each portion of the target and make the thin film has an even thickness, U.S. Pat. No. 6,789,499 provides a sputtering system as shown in FIG. 2, in which each portion of the target can be completely and efficiently sputtered by using a scanning magnetron. When the kinds of the deposition films are not only one, it requires to position more than two kinds of targets in the chamber. U.S. Pat. No. 5,421,973 provides a sputtering system as shown in FIG. 3, in which more than two sputtering guns 31 are adopted to perform the thin film deposition. When the target 33 of one sputtering gun 31 is being sputtered, the other sputtering gun 31 is shaded by a shutter 32 to prevent contamination of the deposition thin film from the other sputtering gun 31. After one kind of thin film is deposited on the substrate 34, the sputtering gun 31 is shaded by the shutter 32 and the other sputtering gun 31 is un-shaded to perform another thin film sputtering. As such, a thin film with an alternating composite multi-layer structure is formed. A feed gas system is installed around the substrate 34 to introduce reactive gas into the chamber so as to control the proportion of a specific component of the thin film. U.S. Pat. No. 6,692,618 provides a sputtering system capable of controlling the composition of the thin film, as shown in FIG. 4, in which more than two kinds of targets 41 and 42 are placed on negative electrodes coupled to a direct current power supply, a rotating magnet 43 is positioned above the backsides of the targets 41 and 42. When the magnet 43 is closed to one of the targets 41 and 42, a specific power from the direct current power supply is supplied to the target 41 or 42 close to the magnet 43. There are much more material deposited on the substrate 44 from the target with magnetic field applied on, but there is less material deposited on the substrate 44 from the target without magnetic field applied on. After passing through a period of time, the magnet 43 is changed to a position close to the other target, and the power of the direct current power supply also can be changed. With this kind of synchronous design, different power can be provided by the direct current power supply while the magnet is shifted to a different position. The composition of the thin film is controlled by this method. A thin film formed of a composite multi-layer structure with periodical composition is formed by this kind of periodical processes.

Referring to FIG. 5A, U.S. Pat. No. 6,709,553 provides another conventional sputtering system, in which a radio frequency bias voltage 51 is applied on the substrate 50. When the deposition of the thin film by magnetron is completed, a direct current power supply 52 or alternating current power supply 53 is turned off, and the radio frequency bias voltage 51 applied to the substrate 50 is turned on, the redundancy film 55 on the bottom of the opening 54 of the substrate 50 is bombarded out by accelerated ions, and then deposited unto the sidewall 56 of the opening 54, as shown in FIG. 5B. U.S. Pat. No. 6,315,872 provides another sputtering system, as shown in FIG. 6, in which coils 62 of an inductively coupled plasma source is disposed between a metal target 61 and a substrate 60. Both of the coils 62 and metal target 61 to be sputtered can be copper or aluminum. When the plasma is lit up by argon gas, the argon gas is turned off, and copper or aluminum atoms sputtered out serve as process gas. The inductively coupled plasma source increases the ionization rate of the copper or aluminum atoms in the chamber such that the copper or aluminum ions can bombard the copper target or aluminum target. Consequently, the chamber is filled with copper atoms or aluminum atoms. During the deposition of a copper layer or an aluminum layer, there is no argon atom present in the chamber, deficiency and pores of the deposition film are reduced.

### SUMMARY OF THE INVENTION

One objective of the present invention is to provide a sputtering system providing large area sputtering and plasma-assisted reactive gas dissociation, which has a plurality of plasma sources to dissociate different reactive gases so as to dope the dissociated reactive gases in the thin film during the deposition of the thin film, and the composition of the thin film can be controlled and the property of the thin film is improved.

It is another objective of the present invention to provide a sputtering system providing large area sputtering and plasma-assisted reactive gas dissociation, in which different plasma sources are used to dissociate different reactive gases in different time sequence such that a composite film can be formed on a substrate.

It is still another objective of the present invention to provide a sputtering system providing large area sputtering and plasma-assisted reactive gas dissociation, in which a plurality of reactive gas plasma sources is used to deposit a thin film on a large-area substrate.

According to the above objectives, the present invention provides a sputtering system providing large area sputtering and plasma-assisted reactive gas dissociation, which comprises a reaction chamber, a substrate holder, a target, an inert gas source, a plurality of plasma sources and a plurality of reactive gas sources. The substrate holder is positioned within the reaction chamber for carrying a substrate. The target is positioned above the substrate holder in the reactive chamber, and the target is connected to a negative bias voltage. The inert gas source is introduced in the reaction chamber for sputtering the target. The plasma sources are positioned at two sides of the target above the substrate holder. The reactive gas sources are respectively introduced in the plasma sources so as to be dissociated by the plasma sources

In one another aspect, the present invention provides a sputtering system providing large area sputtering and plasma-assisted reactive gas dissociation, which comprises a reaction chamber, a substrate holder, at least a target, an inert gas source, a plurality of remote plasma sources and a plurality of reactive gas sources. The substrate holder is positioned within the reaction chamber for carrying a substrate. The target is positioned above the substrate holder in the reaction chamber, and the target is connected to a negative bias voltage. The inert gas source is introduced in the reaction chamber for sputtering the target. The remote plasma sources are positioned above the target and communicate with the reaction chamber. The reaction gas sources are introduced in the plasma sources so as to be dissociated by the plasma sources.

The remote plasma sources can be positioned outside or within the reaction chamber in the present invention. The different reactive gases can be effectively dissociated by the different plasma sources of the present invention such that the dissociated reactive gases can be doped into a thin film during the thin film deposition to control the composition of the thin film. The quality of semiconductor elements formed with the thin film can be improved.

### BRIEF DESCRIPTION OF THE DRAWINGS

FIG. 1 is a schematic view of a structure of a conventional sputtering system;

FIG. 2 is a schematic view of a structure of a conventional sputtering system with movable magnetic field;

FIG. 3 is a schematic view of a structure of a conventional sputtering system with a plurality of sputtering guns;

FIG. 4 is a schematic view of a structure of another conventional sputtering system with movable magnetic field;

FIG. 5A is a schematic view of a structure of a conventional sputtering system with a RF power supply for biasing a substrate;

FIG. 5B depicts schematic cross-sectional views of a substrate at various stages for sputtering a deposition film from a bottom of an opening in the substrate to the sidewall of the opening;

FIG. 6 is a schematic view of a structure of a conventional sputtering system with a high-density plasma source;

FIG. 7A is a schematic cross-sectional view of the sputtering system providing large area sputtering and plasma-assisted reactive gas dissociation according to a first embodiment of the present invention;

FIG. 7B is a schematic perspective view of the sputtering system of the present invention in FIG. 7A;

FIG. 8 is a schematic cross-sectional view of the sputtering system providing large area sputtering and plasma-assisted reactive gas dissociation according to a second embodiment of the present invention;

FIG. 9A is a schematic cross-sectional view of a variance of the sputtering system of the present invention in FIG. 8;

FIG. 9B is a schematic perspective view of a variance with only two capacitively coupled plasma sources;

FIG. 10 is a schematic cross-sectional view of the sputtering system providing large area sputtering and plasma-assisted reactive gas dissociation according to a third embodiment of the present invention; and

FIG. 11 is a schematic cross-sectional view of the sputtering system providing large area sputtering and plasma-assisted reactive gas dissociation according to a fourth embodiment of the present invention.

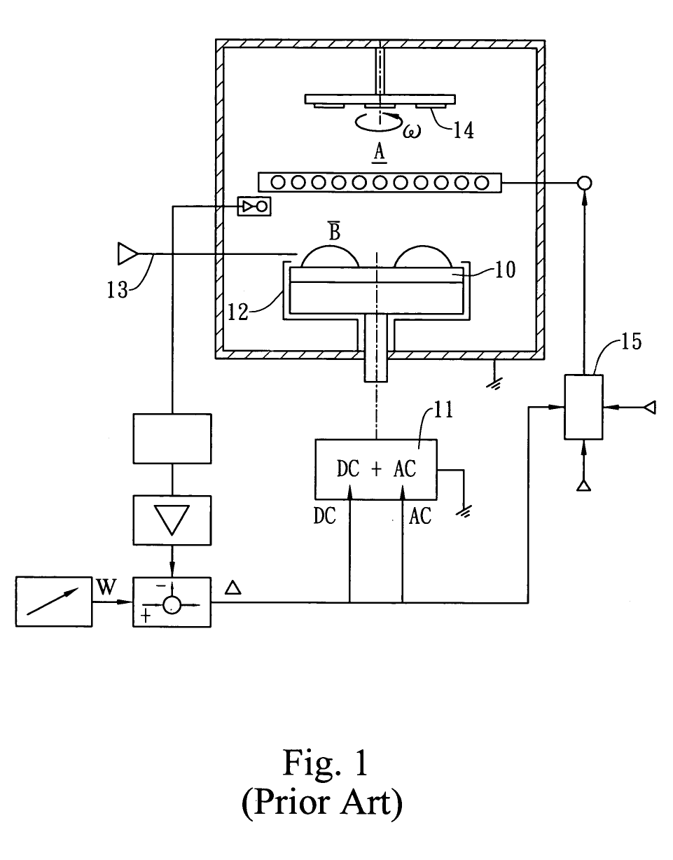

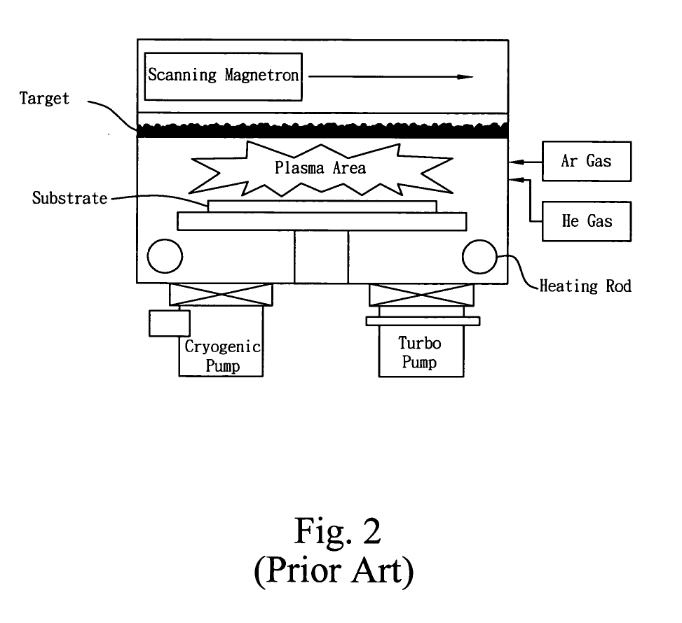

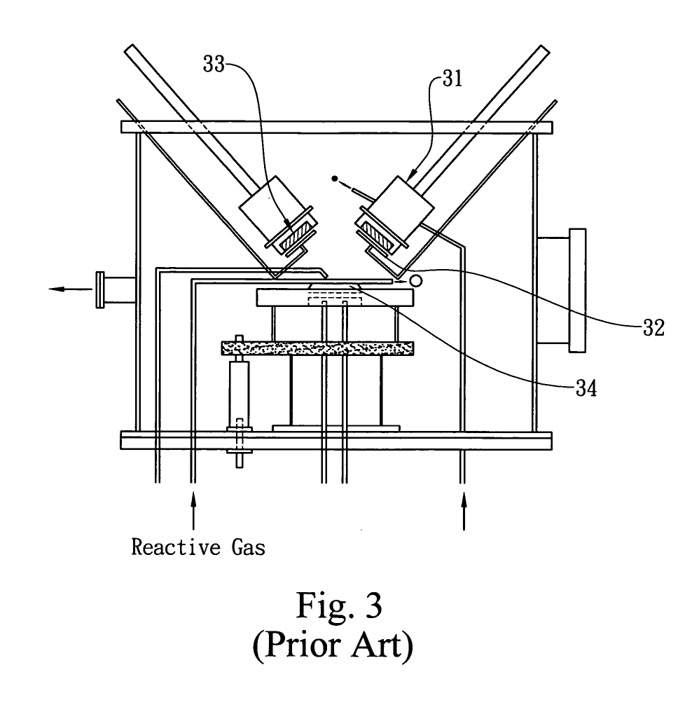

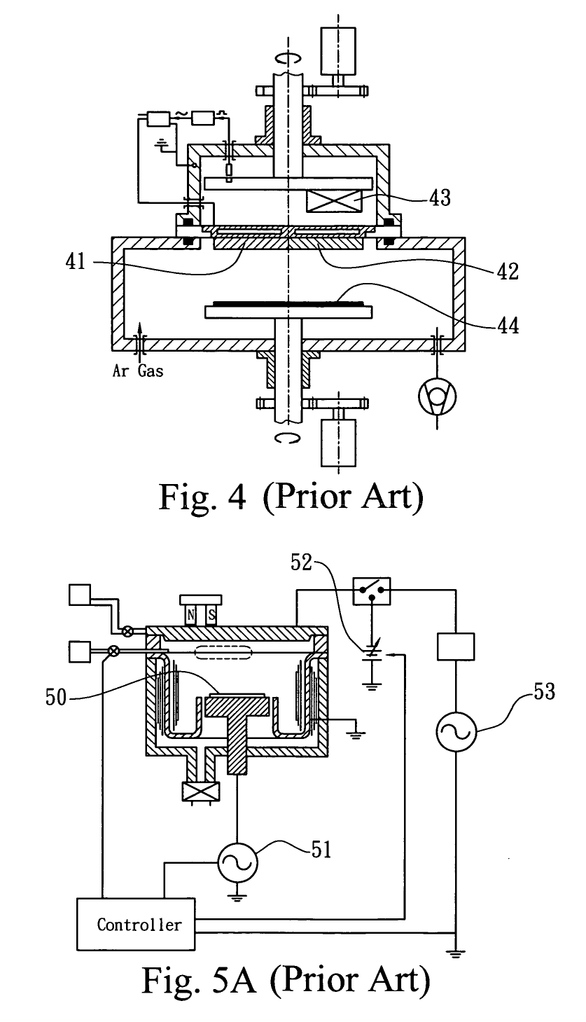

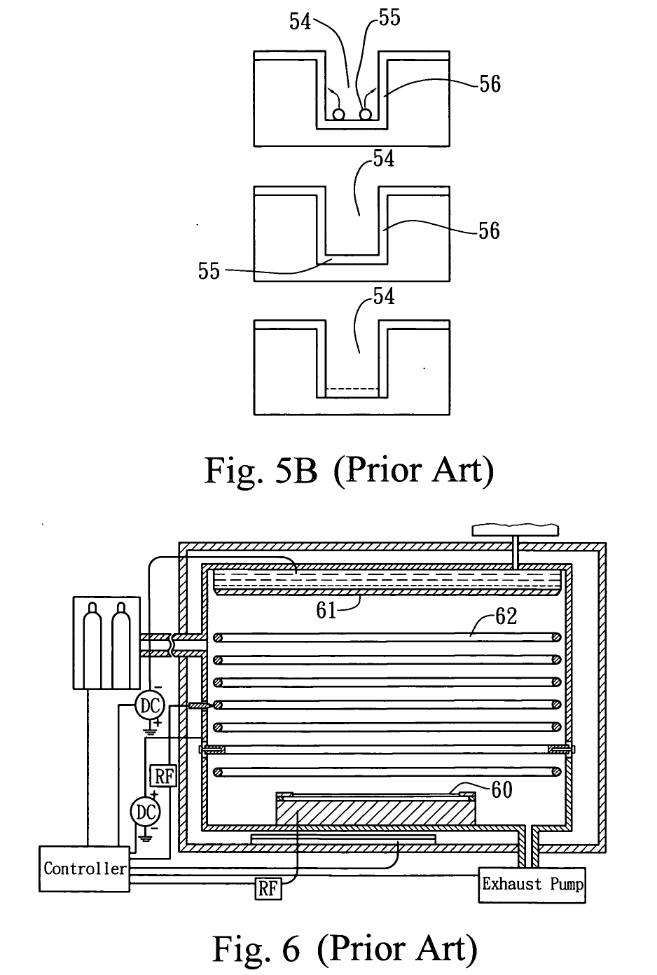

### DETAILED DESCRIPTION OF THE PREFERRED EMBODIMENTS

The present invention provides a sputtering system providing large area sputtering and plasma-assisted reactive gas dissociation, which comprises a plurality of plasma sources. By the plasma sources the reactive gases are dissociated to become atoms and ions, and being doped into a deposition film during a sputtering process for forming the deposition film. By controlling the plasma powers, the pressures of the plasma sources and flow rates of the reactive gases a specific component content of the deposition film can be controlled, and thus improving the quality of the film. The plasma source used to dissociate the reactive gases in the present invention can be inductively coupled plasma source or capacitively coupled plasma source. Further, when the area of the substrate is enlarged, the present sputtering system can use two plasma sources or more positioned in a line to dissociate the reactive gases to become atoms and ions, and hence the atoms and ions can be evenly disposed on the substrate. In addition, by moving the substrate the thin film also can be evenly deposited on the large area substrate. If the substrate is a large area flexible substrate, the thin film can be evenly deposited on the substrate by adopting rollers to move the substrate. Moreover, different reactive gases can be introduced into the different plasma sources in different time sequence so as to form a composite film on the substrate.

A sputtering system providing large area sputtering and plasma-assisted reactive gas dissociation of the present invention will be described and explained in detail by following embodiments with reference to accompanying drawings.

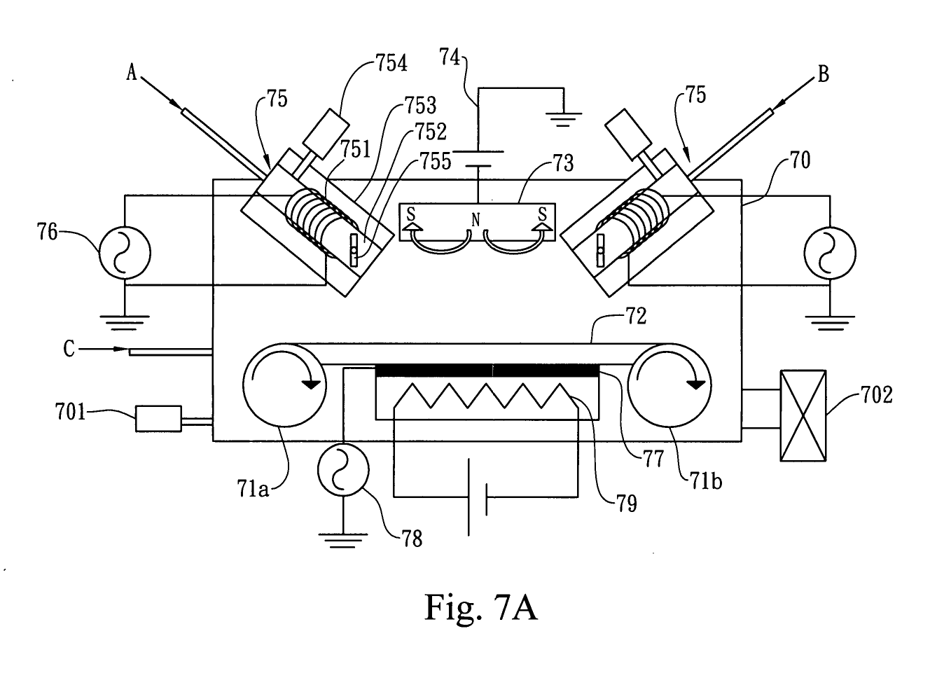

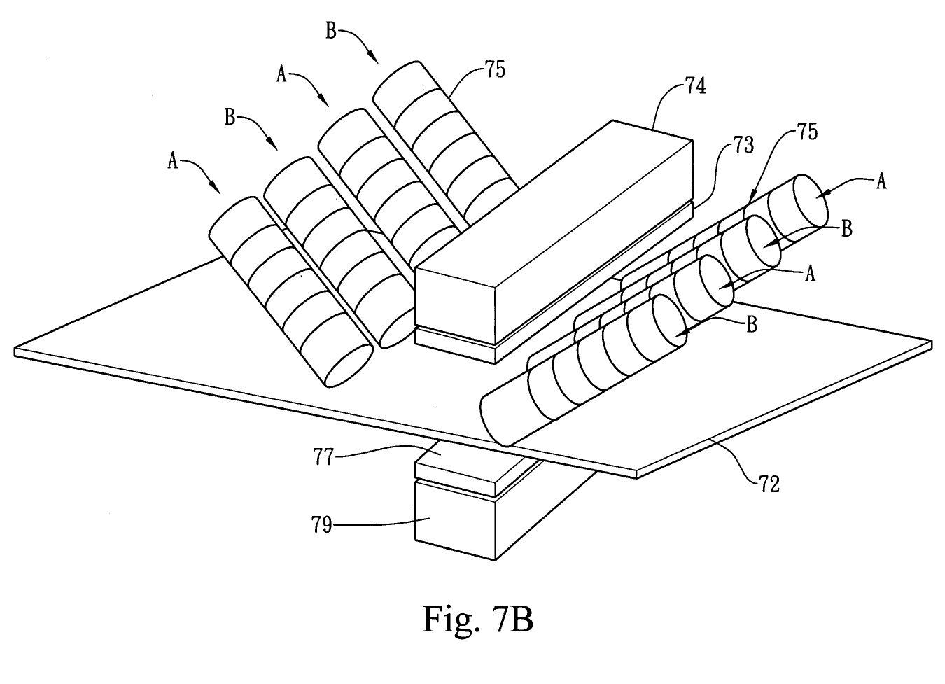

FIG. 7A is a schematic cross-sectional view of the sputtering system providing large area sputtering and plasma-assisted reactive gas dissociation of the first embodiment of the present invention. FIG. 7B is a schematic perspective view of the present sputtering system of FIG. 7A. Referring to FIG. 7A, in the first embodiment, the present sputtering system providing large area sputtering and plasma-assisted reactive gas dissociation comprises a reaction chamber 70, a substrate holder formed of a plurality of rollers 71a and 71b, a conductive target 73, a plurality of inductively coupled plasma sources 75, a plurality of reactive gas sources A and B, an inert gas source C, a conductive electrode 77 and a heater 79. The substrate holder is positioned within the reaction chamber 70 for carrying and moving a large area flexible substrate 72. The conductive target 73 is positioned above the substrate holder in the reaction chamber 70, and the conductive target 73 is coupled to a negative bias of a direct current power supply 74. Referring to FIG. 7B, the inductively coupled plasma sources 75 are positioned in two lines respectively at two sides of the conductive target 73 within the reaction chamber 70. The reactive gases A and B are simultaneously and alternately introduced into the inductively coupled plasma sources 75 to dissociate and ionize the reactive gases A and B. The inductively coupled plasma source 75 is formed of a high dielectric insulating tube 752 wrapped by a conductive coil 751. The high dielectric insulating tube 752 can be a quartz tube or ceramic tube. The conductive coil 751 is coupled to a radio frequency (RF) power supply 76 such that the RF power can be transmitted to the conductive coil 751 for converting the RF power to plasma power. The inductively coupled plasma source 75 is fastened by a supporting tube 753. A first pressure gauge 754 and a throttle valve 755 are assembled inside the inductively coupled plasma source 75. The first pressure gauge 754 is used to monitor the pressure inside the plasma source, and the throttle valve 755 is used to control the pressure inside the plasma source. The chamber of each inductively coupled plasma source 75 is communicant with the reaction chamber 70. The conductive coil 751 of each of the inductive coupled plasma sources 75 is separated from the reaction chamber 70 in order to avoid contamination.

When it is not necessary to use the plasma source in the deposition process, the plasma source is switched off to avoid contamination in the deposition process. The inert gas source C, like argon gas, is introduced in the reaction chamber 70, and the inert gas ions are formed by high voltage ionization. The conductive target 73 is bombarded by the inert gas ions accelerated by the direct current plasma sheath, and the atoms or atom clusters are bombarded out from the conductive target 73. It is preferable that the conductive target 73 is coupled to a magnetron electrode to generate an electric field on the surface of the conductive target 73 so as to bound electrons on the surface of the conductive target 73. As such, ionization density of the inert gas is increased and the sputtering effect is improved. During the sputtering process, the reactive gas A or B is dissociated by the inductively coupled plasma source 57 such that when the target atoms bombarded out from the conductive target 73 are deposited on the substrate 72, the dissociated reactive gas A or B is simultaneously doped into the deposition film to control the composition of the deposition film. The conductive electrode 77 is coupled to the substrate 72 and connected to a RF power supply 78 to bias the substrate 72 so as to increase energy of the ions when being deposited on the substrate 72. As such, the density of the deposition film is increased. The heater 79 is positioned under the substrate holder within the reaction chamber 70 to control the temperature of the film deposition, and furthermore controlling the quality of the deposition film. Besides, the reaction chamber 70 is provided with a second pressure gauge 701 and an exhaust pump 702. The second pressure gauge 701 is used to monitor the pressure inside the reaction chamber 70, and the exhaust pump 702 is used to control the pressure inside the reaction chamber 70. In the first embodiment, the flexible substrate 72 is moved by the rollers 71a and 71b. As such, the thin film can be evenly deposited on the flexible substrate 72. When adopting a large area hard substrate, the hard substrate can be loaded on a movable platform. Further, when the conductive target 73 is replaced by an insulating target, the power applied to the magnetron electrode is replaced by a RF (Radio Frequency) power.

Besides, in the first embodiment, depending on the composition of the deposition film, the plasma sources 75 can be simultaneously introduced only one kind of reactive gas or different reactive gases, or being introduced different reactive gases in different time sequence.

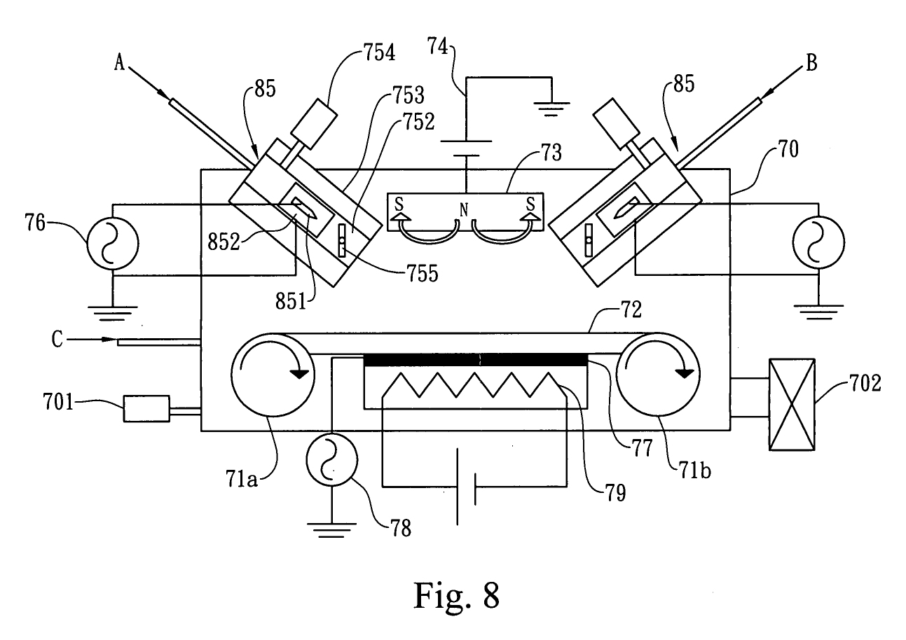

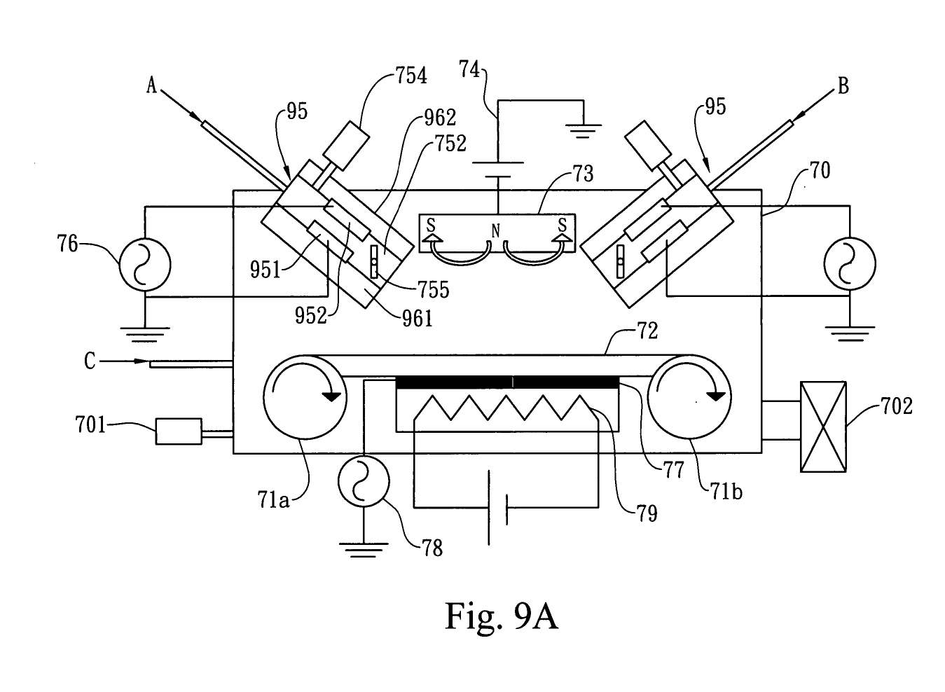

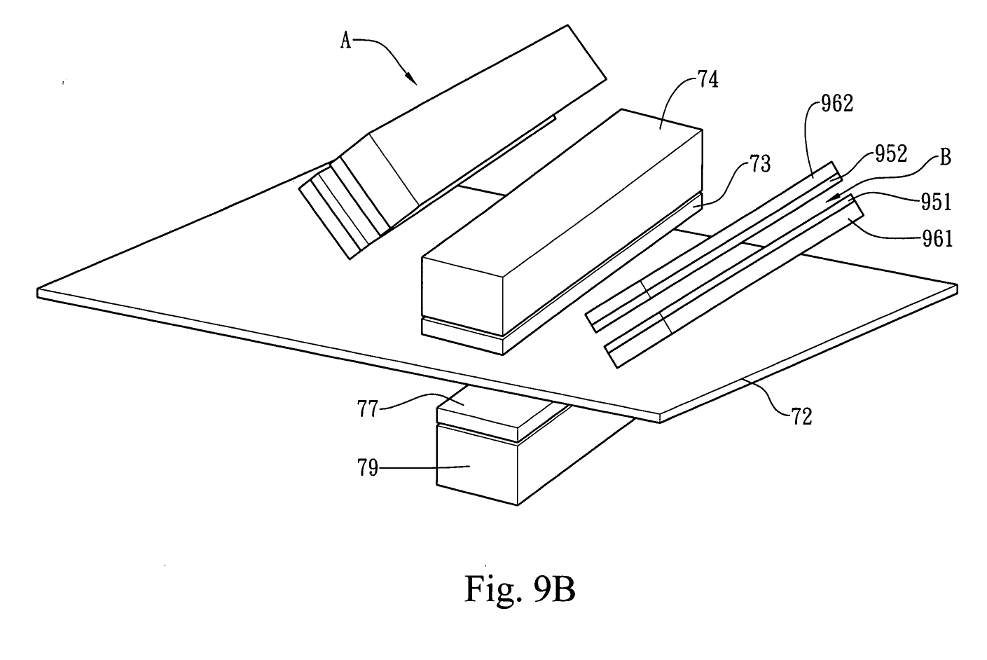

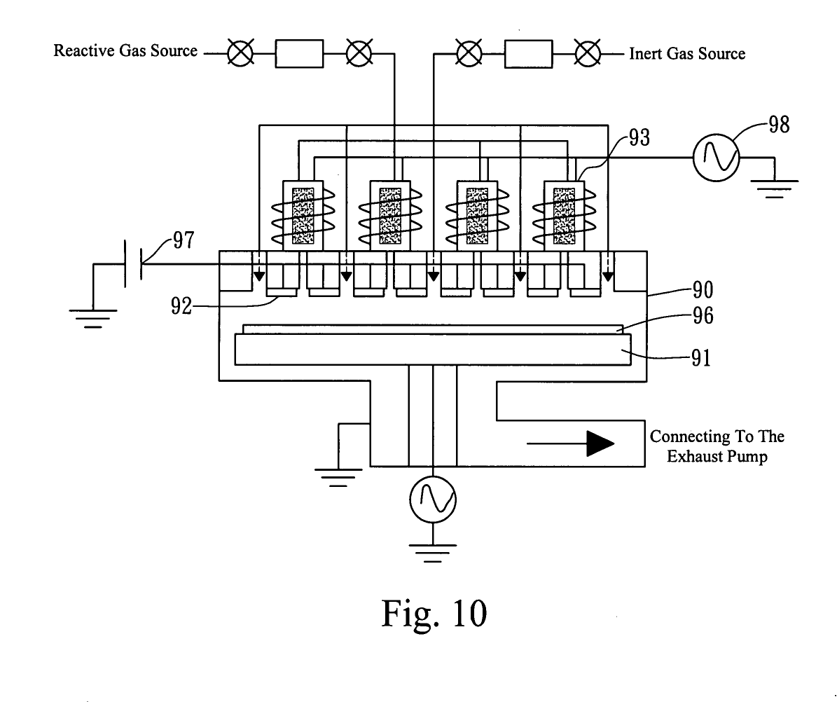

FIG. 8 is a schematic cross-sectional view of the sputtering system providing large area sputtering and plasma-assisted reactive gas dissociation of the second embodiment of the present invention. In the second embodiment, the present sputtering system is provided with a plurality of capacitively coupled plasma sources. In other words, the difference between the-second embodiment and first embodiment is that the inductively coupled plasma source 75 in the first embodiment is replaced by the capacitively coupled plasma source 85 in the second embodiment. Each of the capacitively coupled plasma sources 85 comprises a pair of corresponding conductive electrodes, which can be a pair of coaxial electrodes, like a cylindrical electrode 851 enclosed with a tubular electrode 852. The chamber of each capacitively coupled plasma source is communicant with the reaction chamber 70, and the coaxial tubular electrodes of the capacitively coupled plasma source 85 are separated from the reaction chamber 70 in order to avoid contamination, a pressure gauge 754 and throttle valve 755 are installed in the chamber of each capacitively coupled plasma source 85 to carry out pressure control. Otherwise, each of the capacitively coupled plasma sources 85 comprises two semi-cylinder electrodes facing to each other or a pair of parallel-plate electrodes. FIG. 9A is a schematic cross-sectional view of a variance of the second embodiment, and FIG. 9B is a schematic perspective view of a variance with two capacitively coupled plasma sources. In this variance, the present sputtering system is provided with a pair of the capacitively coupled plasma sources 95 positioned respectively at the two sides of the conductive target 73. Each of the capacitively coupled plasma sources 95 is provided with a pair of the parallel plate electrodes 951 and 952 that are fastened by the supporting members 961 and 962. The parallel plate electrodes 951 and 952 are connected to the RF power supply 76 such that the plasma is generated between the parallel plate electrodes 951 and 952 during introducing the reactive gas into the space between the parallel plate electrodes 951 and 952. Each pair of the parallel plate electrodes is driven by a RF power supply, and the chamber of each capacitively coupled plasma-source 95 is communicant with the reaction chamber 70. The parallel plate electrodes of the capacitively coupled plasma source 95 is separated from the reaction chamber 70 in order to avoid contamination, a pressure gauge 754 and throttle valve 755 are installed in the chambers of the capacitively coupled plasma source to carry out pressure control FIG. 10 is a schematic cross-sectional view of the sputtering system providing large area sputtering and plasma-assisted reactive gas dissociation of the third embodiment of the present invention. In the third embodiment, the present sputtering system comprises a reaction chamber 90, a substrate holder 91 on which a bias voltage is applied by a conductive electrode and a heater is provided to control the temperature of a substrate placed thereon, a plurality of targets 92, an inert gas source, a plurality of remote plasma sources 93 and at least one reactive gas source. The substrate holder 91 is a platform positioned in the reaction chamber 90 for supporting a substrate 96. The targets 92 are positioned above the substrate holder 91 in the reaction chamber 90, and each of the targets 92 is connected to a negative bias 97. As the same with the above-mentioned in the first embodiment, the negative bias 97 is supplied by a magnetron electrode. When the target 92 is formed of conductive material, a direct current power supply is used to provide power to the Magnetron electrode. However, when the target 92 is an insulating material, the direct current power is changed to RF power. The inert gas source, such as argon gas, positioned above the reaction chamber 90 is introduced into the reaction chamber 90 via multi-channels. The inert gas source is used to sputter the targets 92. The remote plasma sources 93 positioned above the targets 92 and connected to the inside of the reaction chamber 90 are the inductively coupled plasma sources. The inductively coupled plasma sources are coupled to a RF power supply 98 so as to provide a plasma power to the inductively coupled plasma sources. At least one reactive gas source is introduced into the remote plasma sources 93 respectively to be dissociated by the remote plasma sources 93. The conductive electrode of the substrate holder 91 is connected to a RF power supply 94 and coupled to the substrate 96 to bias the substrate 96. As such, the energy of the ion deposition on the substrate 96 is increased and the density of the thin film is improved. The heater positioned below the substrate holder 91 of the reaction chamber 90 is used to control the temperature of the film deposition so as to control the quality of the thin film. In the third embodiment, the substrate 96 can be a large area hard substrate or large area flexible substrate. The substrate holder 91 can be a roller type to support and move the flexile substrate when the substrate 96 is the large area flexible substrate.

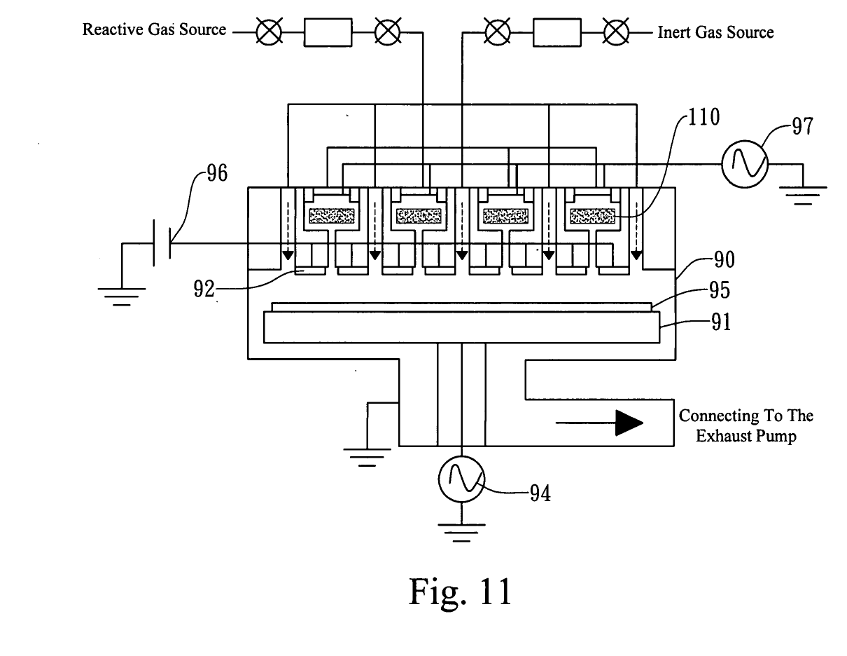

FIG. 11 shows a schematic cross-sectional view of the sputtering system providing large area sputtering and plasma-assisted reactive gas dissociation of the third embodiment of the present invention. The difference between the third and fourth embodiments is that the inductively coupled plasma sources of the third embodiment are replaced by a plurality of remote capacitively coupled plasma sources 110 in the fourth embodiment. The remote capacitively coupled plasma sources 110 are positioned above the targets 92 within the reaction chamber 90.

While the invention has been described by way of examples and in terms of preferred embodiments, it is to be understood that those who are familiar with the subject art can carry out various modifications and similar arrangements and procedures described in the present invention and also achieve the effectiveness of the present invention. Hence, it is to be understood that the description of the present invention should be accorded with the broadest interpretation to those who are familiar with the subject art, and the invention is not limited thereto.

What is claimed is:

1. A sputtering system providing large area sputtering and plasma-assisted reactive gas dissociation, comprising:
a reaction chamber;
a substrate holder positioned within said reaction chamber for carrying a substrate;
a target positioned above said substrate holder in said reactive chamber, said target connected to a negative bias voltage;
an inert gas source introduced in said reaction chamber for sputtering said target;
a plurality of plasma sources positioned at two sides of said target above said substrate holder; and
a plurality of reactive gas sources being respectively introduced in said plasma sources so as to be dissociated by said plasma sources.

2. The sputtering system providing large area sputtering and plasma-assisted reactive gas dissociation as claimed in claim 1, wherein said plasma sources are inductively coupled plasma sources, each of said inductively coupled plasma sources includes a dielectric tube and a conductive coil wrapping said dielectric tube, and each coil is driven by a RF power supply, the chambers of said inductively coupled plasma source are communicant with said reaction chamber, and said conductive coils of said inductive coupled plasma source are separated from said reaction chamber in order to avoid contamination, a pressure gauge and throttle valve are installed in said chambers of said inductively coupled plasma source to carry out pressure control.

3. The sputtering system providing large area sputtering and plasma-assisted reactive gas dissociation as claimed in claim 1, wherein said plasma sources are capacitively coupled plasma sources.

4. The sputtering system providing large area sputtering and plasma-assisted reactive gas dissociation as claimed in claim 3, wherein each of said capacitively coupled plasma sources includes a pair of coaxial tubular electrodes, each pair of said coaxial tubular electrodes is driven by a RF power supply, the chambers of said capacitively coupled plasma source are communicant with said reaction chamber, and said coaxial tubular electrodes of said capacitively coupled plasma source are separated from said reaction chamber in order to avoid contamination, a pressure gauge and throttle valve are installed in said chamber of each said capacitively coupled plasma source to carry out pressure control.

5. The sputtering system providing large area sputtering and plasma-assisted reactive gas dissociation as claimed in claim 3, wherein each of said capacitively coupled plasma sources includes a pair of parallel plate electrodes, each pair of said parallel plate electrodes is driven by a RF power supply, and the chambers of said capacitively coupled plasma source are communicant with said reaction chamber, said parallel plate electrodes of said capacitively coupled plasma source are separated from said reaction chamber in order to avoid contamination, a pressure gauge and throttle valve are installed in the chambers of the capacitively coupled plasma source to carry out pressure control.

6. The sputtering system providing large area sputtering and plasma-assisted reactive gas dissociation as claimed in claim 1, wherein said substrate holder is a supporting platform.

7. The sputtering system providing large area sputtering and plasma-assisted reactive gas dissociation as claimed in claim 1, wherein said substrate holder is comprised of a plurality of rollers.

8. The sputtering system providing large area sputtering and plasma-assisted reactive gas dissociation as claimed in claim 1, wherein said target is associated with a magnetron electrode connected to a negative bias to produce electric field on a surface of said target.

9. The sputtering system providing large area sputtering and plasma-assisted reactive gas dissociation as claimed in claim 1, wherein further comprises a conductive electrode associated with said substrate holder so as to apply a bias voltage on said substrate.

10. The sputtering system providing large area sputtering and plasma-assisted reactive gas dissociation as claimed in claim 1, wherein further comprises a heater associated with said substrate holder to control the temperature of said substrate.

11. The sputtering system providing large area sputtering and plasma-assisted reactive gas dissociation as claimed in claim 9, wherein further comprises a heater associated with said substrate holder to control the temperature of said substrate.

12. The sputtering system providing large area sputtering and plasma-assisted reactive gas dissociation as claimed in claim 1, wherein said reactive gas sources at least include a kind of reactive gas.

13. The sputtering system providing large area sputtering and plasma-assisted reactive gas dissociation as claimed in claim 2, wherein said reactive gas sources at least include a kind of reactive gas.

14. The sputtering system providing large area sputtering and plasma-assisted reactive gas dissociation as claimed in claim 3, wherein said reactive gas sources at least include a kind of reactive gas.

15. A sputtering system providing large area sputtering and plasma-assisted reactive gas dissociation, comprising:
a reaction chamber;
a substrate holder positioned within said reaction chamber for carrying a substrate;
at least a target positioned above said substrate holder in said reactive chamber, said target connected to a negative bias voltage;
an inert gas source introduced in said reaction chamber for sputtering said target;
a plurality of remote plasma sources positioned above said target and communicating with said reactive chamber; and
at least a reactive gas source introduced in said plasma sources so as to be dissociated by said plasma sources.

16. The sputtering system providing large area sputtering and plasma-assisted reactive gas dissociation as claimed in claim 15, wherein said remote plasma sources are positioned outside said reaction chamber.

17. The sputtering system providing large area sputtering and plasma-assisted reactive gas dissociation as claimed in claim 15, wherein said remote plasma sources are positioned within said reaction chamber.

18. The sputtering system providing large area sputtering and plasma-assisted reactive gas dissociation as claimed in claim 15, wherein said remote plasma sources are inductively coupled plasma sources.

19. The sputtering system providing large area sputtering and plasma-assisted reactive gas dissociation as claimed in claim 15, wherein said remote plasma sources are capacitively coupled plasma sources.

20. The sputtering system providing large area sputtering and plasma-assisted reactive gas dissociation as claimed in claim 15, wherein said reactive gases at least include a kind of reactive gas.

21. The sputtering system providing large area sputtering and plasma-assisted reactive gas dissociation as claimed in claim 15, wherein said target is associated with a magnetron electrode connected to a negative bias voltage so as to produce electric field on a surface of said target.

22. The sputtering system providing large area sputtering and plasma-assisted reactive gas dissociation as claimed in claim 15, wherein further comprises a conductive electrode associated with said substrate holder to apply a bias voltage on said substrate.

23. The sputtering system providing large area sputtering and plasma-assisted reactive gas dissociation as claimed in claim 15, wherein further comprises a heater associated with said substrate holder to control the temperature of said substrate.

24. The sputtering system providing large area sputtering and plasma-assisted reactive gas dissociation as claimed in claim 15, wherein said substrate holder is a supporting platform.

25. The sputtering system providing large area sputtering and plasma-assisted reactive gas dissociation as claimed in claim 15, wherein said substrate holder is comprised of a plurality of rollers.

26. The sputtering system providing large area sputtering and plasma-assisted reactive gas dissociation as claimed in claim 18, wherein said reactive gases at least include a kind of reactive gas.

27. The sputtering system providing large area sputtering and plasma-assisted reactive gas dissociation as claimed in claim 19, wherein said reactive gases at least include a kind of reactive gas.
